(19) United States
(12) Patent Application Publication
(10) Pub. No.: US 2026/0123457 A1
(43) Pub. Date: Apr. 30, 2026

(54) TRANSISTOR THROUGH-HOLE PACKAGE MODULE

(71) Applicant: Raytrons Power Limited, Hong Kong (CN)

(72) Inventor: WAI KIN RAYMOND LAM, Hong Kong (CN)

(73) Assignee: Raytrons Power Limited, Hong Kong (CN)

(21) Appl. No.: 19/185,155

(22) Filed: Apr. 21, 2025

(30) Foreign Application Priority Data
Oct. 29, 2024 (CN) 202422629461.7

(51) Int. Cl. H01L 23/495; H01L 23/367; H01L 23/373

(52) U.S. Cl. CPC H10W 70/461; H10W 40/22; H10W 40/258; H10W 70/481

(57) ABSTRACT

A transistor through-hole package module includes: an insulating package body and at least one transistor encapsulated therein; a lead frame including through-hole pins extending from the insulating package body and a die pad disposed within the insulating package body. The transistor is mounted on the die pad and electrically connected to the through-hole pins; a metal heat sink plate that is partially exposed from the insulating package body. Both the metal heat sink plate and the lead frame are formed of copper or copper alloy, and the side of the lead frame facing away from the transistor is bonded to the metal heat sink plate via a thermally conductive insulating adhesive. The package module of the present disclosure offers the advantage of superior heat dissipation performance.

### CROSS-REFERENCE TO RELATED APPLICATIONS

This application claims priority to Chinese Patent Application No. 202422629461.7, filed on Oct. 29, 2024, the content of which is incorporated herein by reference in its entirety.

### TECHNICAL FIELD

The present disclosure relates to the field of semiconductor packaging; more specifically, it relates to a transistor through-hole package module.

### BACKGROUND

Through-hole package modules have pins that may be directly inserted into mounting holes on circuit boards. This packaging method provides a more secure connection between the package module and the circuit board, thereby helping to improve product reliability and stability.

In the prior art, transistor through-hole package modules mainly dissipate heat through the through-hole pins of the lead frame, which results in poor heat dissipation performance that needs improvement.

### SUMMARY

The main object of the present disclosure is to provide a transistor through-hole package module with improved heat dissipation performance.

To achieve the above main object, the present disclosure provides a transistor through-hole package module, comprising:
an insulating package body and at least one transistor encapsulated therein;
a lead frame comprising a plurality of through-hole pins extending from the insulating package body and a die pad disposed within the insulating package body, wherein the transistor is mounted on the die pad and electrically connected to the through-hole pins; and
a metal heat sink plate configured to be partially exposed from the insulating package body, wherein the metal heat sink plate and the lead frame are formed of copper or copper alloy, and a side of the lead frame facing away from the transistor is bonded to the metal heat sink plate via a thermally conductive insulating adhesive.

According to a specific embodiment of the present disclosure, the thermally conductive insulating adhesive has a thickness of 0.1 mm to 0.15 mm.

According to a specific embodiment of the present disclosure, the thermally conductive insulating adhesive has a thermal conductivity greater than 3 W/m·K.

According to a specific embodiment of the present disclosure, the through-hole pins are configured to extend from a first side of the insulating package body, the metal heat sink plate has a heat dissipation portion extending from a second side of the insulating package body, and the second side is opposite to the first side.

Furthermore, the heat dissipation portion comprises grooved portions formed on opposing sides thereof in a width direction.

According to a specific embodiment of the present disclosure, a surface of the metal heat sink plate facing away from the thermally conductive insulating adhesive forms a heat dissipation surface exposed from the insulating package body.

Furthermore, when viewed in a thickness direction of the metal heat sink plate, the heat dissipation surface is configured not to exceed the insulating package body.

According to a specific embodiment of the present disclosure, the die pad is integrally formed with one of the plurality of through-hole pins.

According to a specific embodiment of the present disclosure, the plurality of through-hole pins are arranged linearly.

According to a specific embodiment of the present disclosure, the through-hole pins comprise bent portions disposed within the insulating package body.

The technical solution of the present disclosure has the following beneficial effects:

In the package module of the present disclosure, the metal heat sink plate and the lead frame are thermally connected via a thermally conductive insulating adhesive, both being formed of copper or copper alloy with excellent thermal conductivity properties. The transistor can dissipate heat not only through the pins of the lead frame but also through the metal heat sink plate that is exposed from the insulating package body, thus achieving superior heat dissipation performance. Furthermore, the metal heat sink plate and the lead frame are bonded via a thermally conductive insulating adhesive to provide fixing and heat conduction, thereby offering the advantages of convenient manufacturing and low cost.

To more clearly illustrate the object, technical solution, and advantages of the present disclosure, detailed description will be given below in conjunction with the drawings and specific embodiments.

### BRIEF DESCRIPTION OF THE DRAWINGS

FIG. 1 is a schematic view showing an overall structure of the package module according to the first embodiment.

FIG. 2 is a schematic view showing an overall structure of the substrate assembly according to the first embodiment.

FIG. 3 is a schematic exploded structural view of the substrate assembly according to the first embodiment.

FIG. 4 is a schematic structural view showing a variation of the substrate assembly according to the first embodiment.

FIG. 5 is a schematic view showing an overall structure of the package module according to the second embodiment.

FIG. 6 is a schematic view showing an overall structure of the substrate assembly according to the second embodiment.

FIG. 7 is a schematic exploded structural view of the substrate assembly according to the second embodiment.

FIG. 8 is a schematic structural view showing a variation of the substrate assembly according to the second embodiment.

### DETAILED DESCRIPTION OF THE EMBODIMENTS

In the following description, many specific details are provided to fully understand the present disclosure, but it should be understood that the present disclosure can be implemented in various ways different from those described herein. Therefore, the protection scope of the present disclosure is not limited to the specific embodiments disclosed herein.

### First Embodiment

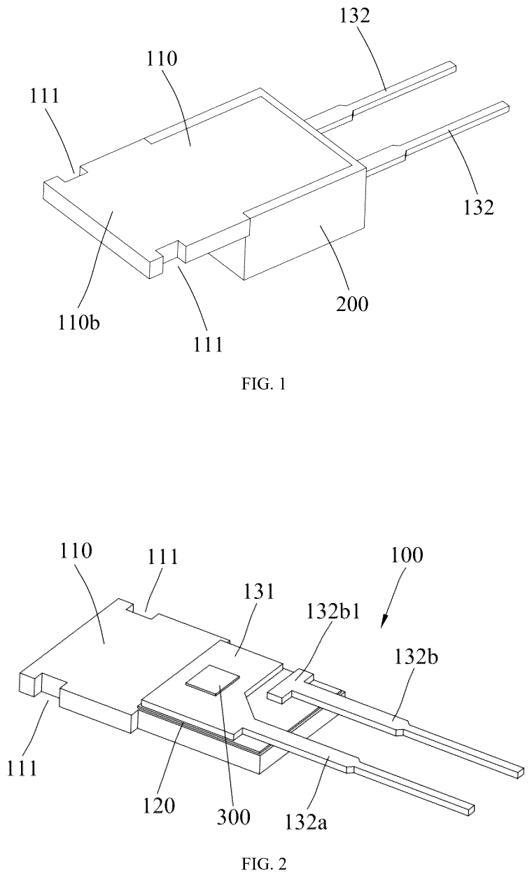

As shown in FIGS. 1 to 3, the transistor through-hole package module according to the first embodiment includes a substrate assembly 100, an insulating package body 200 formed of, for example, resin, and at least one transistor 300 encapsulated in the insulating package body 200. The transistor 300 may be a MOSFET chip or an IGBT chip, but is not limited thereto. The substrate assembly 100 includes a metal heat sink plate 110 and a lead frame 130, wherein a side of the lead frame 130 facing away from the transistor 300 is bonded to the metal heat sink plate 110 via a thermally conductive insulating adhesive 120. The metal heat sink plate 110 and the lead frame 130 are formed of copper or copper alloy.

In the present disclosure, the thickness of the thermally conductive insulating adhesive 120 may be determined based on factors such as the voltage withstand performance, connection strength, and heat conduction requirements between the lead frame 130 and the metal heat sink plate 110. The specific thickness may be from 0.1 mm to 0.15 mm, but is not limited thereto. The thermal conductivity of the thermally conductive insulating adhesive 120 is preferably greater than 3 W/m·K, more preferably greater than 5 W/m·K, for example 10 W/m·K.

The lead frame 130 includes a plurality of through-hole pins 132 extending from a first side of the insulating package body 200 and a die pad 131 disposed within the insulating package body 200. The transistor 300 is mounted on the surface of the die pad 131 facing away from the thermally conductive insulating adhesive 120 and electrically connected to the through-hole pins 132. Preferably, the die pad 131 is integrally formed with one of the plurality of through-hole pins 132 to simplify the structure of the lead frame 130.

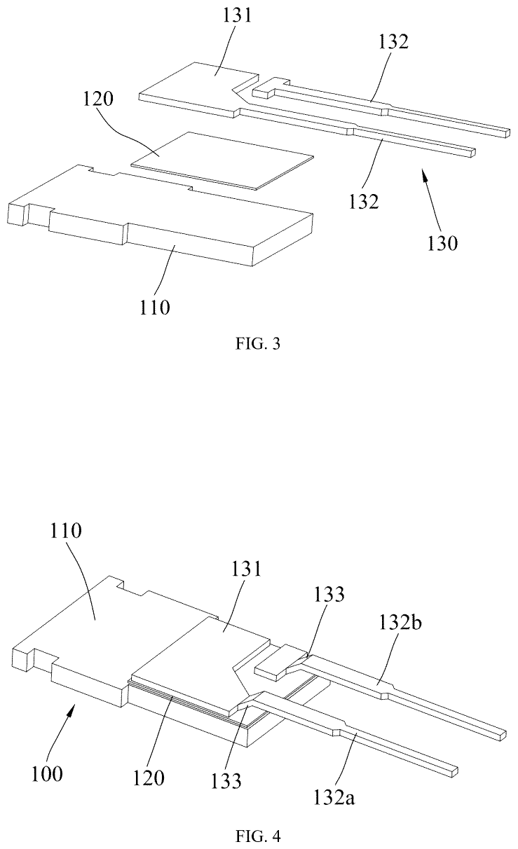

The plurality of through-hole pins 132 are preferably arranged linearly. According to the first embodiment, as shown in FIGS. 2 and 3, the plurality of through-hole pins 132 include a first pin 132a and a second pin 132b each having planar structures. The die pad 131 is integrally formed with the first pin 132a, and the transistor 300 mounted on the die pad 131 may be electrically connected to the first pin 132a via the die pad 131. The transistor 300 may be electrically connected to the bonding pad 132b1 of the second pin 132b through a conductive wire (such as a gold wire or silver wire), thereby establishing electrical connection to the second pin 132b. The bonding pad 132b1 and the conductive wire are encapsulated within the insulating package body 200.

The metal heat sink plate 110 is configured to be partially exposed from the insulating package body 200 for connection to an external heat sink or for direct heat dissipation. According to the first embodiment, the metal heat sink plate 110 comprises a heat dissipation portion 110b extending from a second side of the insulating package body 200, and the second side is opposite to the first side. Preferably, the heat dissipation portion 110b comprises grooved portions 111 formed on opposing sides thereof in a width direction.

As a variation of the first embodiment, as shown in FIG. 4, each of the plurality of through-hole pins 132, including the first pin 132a and the second pin 132b, comprises a bent portion 133 disposed within the insulating package body 200.

### Second Embodiment

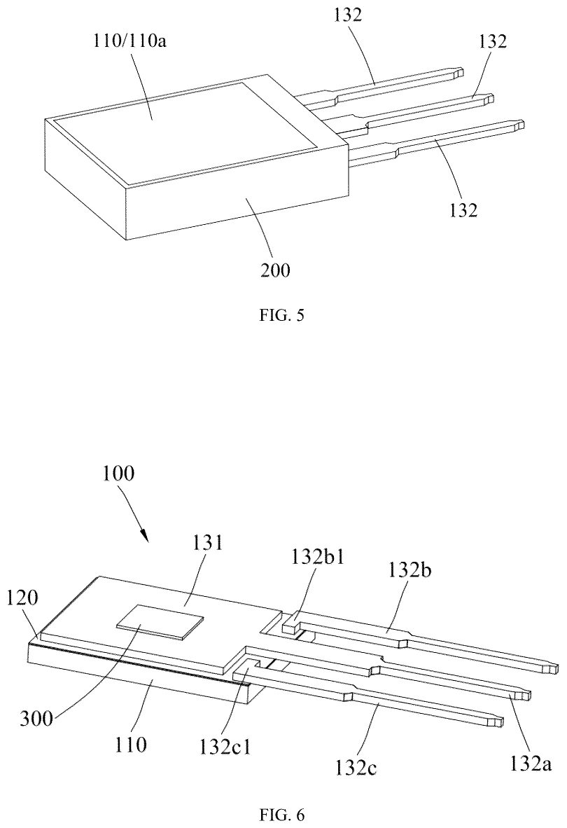

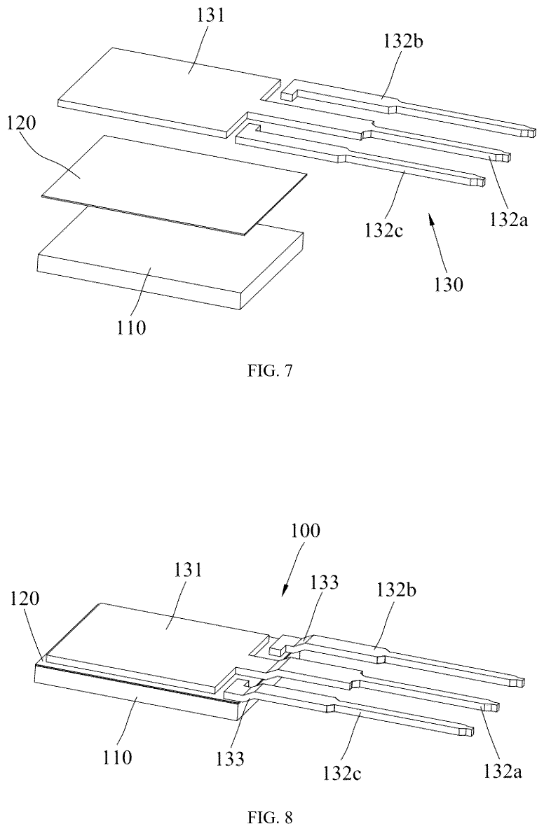

As shown in FIGS. 5 to 7, the transistor through-hole package module according to the second embodiment includes a substrate assembly 100, an insulating package body 200, and at least one transistor 300 encapsulated in the insulating package body 200. The substrate assembly 100 includes a metal heat sink plate 110 and a lead frame 130, wherein a side of the lead frame 130 facing away from the transistor 300 is bonded to the metal heat sink plate 110 via thermally conductive insulating adhesive 120. The lead frame 130 includes a plurality of through-hole pins 132 extending from the insulating package body 200 and a die pad 131 disposed within the insulating package body 200. The transistor 300 is mounted on a surface of the die pad 131 facing away from the thermally conductive insulating adhesive 120 and electrically connected to the through-hole pins 132.

Exemplarily, the plurality of through-hole pins 132 include linearly arranged first pin 132a, second pin 132b, and third pin 132c. The die pad 131 is integrally formed with the first pin 132a, and the transistor 300 mounted on the die pad 131 may be electrically connected to the first pin 132a via the die pad 131. The transistor 300 may be electrically connected to both the bonding pad 132b1 of the second pin 132b and the bonding pad 132c1 of the third pin 132c through conductive wires (such as gold wires or silver wires), thereby establishing electrical connections to the second pin 132b and the third pin 132c. The bonding pad 132b1, the bonding pad 132c1, and the conductive wires are encapsulated within the insulating package body 200.

According to the second embodiment, as shown in FIG. 5, a surface of the metal heat sink plate 110 facing away from the thermally conductive insulating adhesive 120 forms a heat dissipation surface 110a that is exposed from the insulating package body 200. Preferably, when viewed in the thickness direction of the metal heat sink plate 110, the heat dissipation surface 110a is configured not to exceed the insulating package body 200, which helps achieve miniaturization of the package module. The heat dissipation surface 110a may be flush with a surface of the insulating package body 200 or may have a height difference.

As a variation of the second embodiment, as shown in FIG. 8, each of the plurality of through-hole pins 132, including the first pin 132a, the second pin 132b, and the third pin 132c, comprises a bent portion 133 disposed within the insulating package body 200.

For other descriptions of the second embodiment, reference may be made to the first embodiment, which will not be repeated here.

In conclusion, in the transistor through-hole package module of the present disclosure, the metal heat sink plate 110 and the lead frame 130 are thermally connected, enabling the transistor 300 to dissipate heat not only through the through-hole pins 132 of the lead frame 130 but also through the metal heat sink plate 110 that is exposed from the insulating package body 200, thus achieving superior heat dissipation performance. The metal heat sink plate 110 and the lead frame 130 are bonded via a thermally conductive insulating adhesive 120 to provide fixing, thermal conduction, and electrical insulation, thereby providing the advantages of convenient manufacturing and low cost.

Although the above embodiments illustrate the present disclosure, it should be understood that these embodiments are provided only for exemplary purposes to describe possible implementations of the present disclosure and should not be construed as limiting the scope of protection. Any equivalent variations made by those skilled in the art in accordance with the present disclosure should likewise fall within the scope of protection of the claims of the present disclosure.

What is claimed is:

1. A transistor through-hole package module, comprising:
an insulating package body and at least one transistor encapsulated in the insulating package body;
a lead frame comprising a plurality of through-hole pins extending from the insulating package body and a die pad disposed within the insulating package body, wherein the transistor is mounted on the die pad and electrically connected to the through-hole pins; and
a metal heat sink plate configured to be partially exposed from the insulating package body, wherein the metal heat sink plate and the lead frame are formed of copper or copper alloy, and a side of the lead frame facing away from the transistor is bonded to the metal heat sink plate via a thermally conductive insulating adhesive.

2. The transistor through-hole package module according to claim 1, wherein the thermally conductive insulating adhesive has a thickness of 0.1 mm to 0.15 mm.

3. The transistor through-hole package module according to claim 1, wherein the thermally conductive insulating adhesive has a thermal conductivity greater than 3 W/m·K.

4. The transistor through-hole package module according to claim 1, wherein the through-hole pins are configured to extend from a first side of the insulating package body, the metal heat sink plate has a heat dissipation portion extending from a second side of the insulating package body, and the second side is opposite to the first side.

5. The transistor through-hole package module according to claim 4, wherein the heat dissipation portion comprises grooved portions formed on opposing sides of the heat dissipation portion in a width direction.

6. The transistor through-hole package module according to claim 1, wherein a surface of the metal heat sink plate facing away from the thermally conductive insulating adhesive forms a heat dissipation surface exposed from the insulating package body.

7. The transistor through-hole package module according to claim 6, wherein when viewed in a thickness direction of the metal heat sink plate, the heat dissipation surface is configured not to exceed the insulating package body.

8. The transistor through-hole package module according to claim 1, wherein the die pad is integrally formed with one of the plurality of through-hole pins.

9. The transistor through-hole package module according to claim 1, wherein the plurality of through-hole pins are arranged linearly.

10. The transistor through-hole package module according to claim 1, wherein the through-hole pins comprise bent portions disposed within the insulating package body.
